(19) United States
(12) Patent Application Publication
(10) Pub. No.: US 2005/0218482 A1
(43) Pub. Date: Oct. 6, 2005

(54) Top finger having a groove and semiconductor device having the same

(76) Inventors: Peter Chou, Taipei (TW); Cindy Ding, Tianjin (TW); Anne Hao, Tianjin (TW)

Correspondence Address: MAYER, FORTKORT & WILLIAMS, PC, 251 NORTH AVENUE WEST, 2ND FLOOR, WESTFIELD, NJ, 07090, US

(21) Appl. No.: 10/816,295

(22) Filed: Apr. 1, 2004

(51) Int. Cl. H01L 23/495

(52) U.S. Cl. 257/666

(57) ABSTRACT

To provide a robust soldering process for a top finger of a surface mount device, a lead frame having a top finger and a semiconductor device having the same are disclosed, wherein the top finger comprises a groove and the groove is provided at the bottom surface of the top finger that establishes contact with a die and adjacent to the contact position between the top finger and die so as to prevent solder from overflowing onto a chip passivation ring, reducing the stress on the die and increasing the reliability.

### BACKGROUND OF THE INVENTION

1. Field of the Invention

The present invention generally relates to a semiconductor device, and more particularly to a surface mount semiconductor device with a structure that includes a groove to prevent solder overflow.

2. Description of the Related Art

FIG. 1 illustrates a semiconductor device manufactured according to a conventional soldering process. A die (12) is attached on a lead frame (10) and then a top finger or clip (11) is attached on the die (12). For a pre-bump or solder paste process of a clip design device, it is easy to find a potential failure occurring on the top side of the die (12). The potential failure is frequently caused by solder (14) overflowing onto a passivation ring (13). Such an overflow will increase the stress on the passivation ring (13) thereby causing a higher leakage or a potential reliability problem.

There are many known ways to prevent solder from overflowing onto the passivation ring. One way is to increase the distance between the top finger and the die so as to increase the dimple height. However, this method will also increase the mechanical stress on the die and deteriorate soldering quality as well. Another way is to reduce the solder volume to prevent the solder from overflowing onto the passivation ring. However, such a way will increase the forward voltage as well.

### SUMMARY OF THE INVENTION

A lead frame having a top finger and a semiconductor device having the same are disclosed. The top finger includes a groove and the groove is provided at the bottom side of the top finger and adjacent to the contact position between the top finger and a die, so as to prevent solder from overflowing onto a chip passivation ring, reducing the stress on the die and increasing the reliability.

Preferably, the groove of the top finger is a U or V-groove.

### BRIEF DESCRIPTION OF THE DRAWINGS

For a more complete understanding of the present invention and the advantages thereof, reference is now made to the following descriptions taken in conjunction with the accompanying drawings which illustrate the embodiments of the present invention, wherein:

FIG. 1 illustrates a cross-sectional view of a semiconductor device manufactured according to a conventional soldering process;

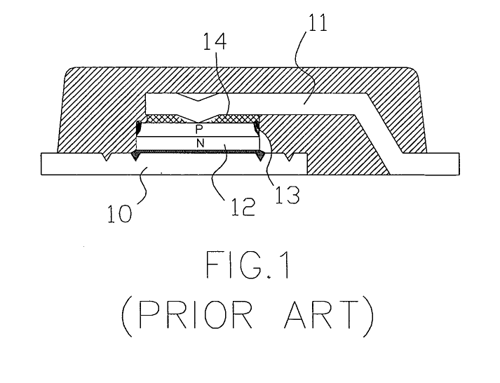

FIG. 2 illustrates a cross-sectional view of a semiconductor device manufactured according to one embodiment of a lead frame in accordance with the present invention; and

FIG. 3 illustrates a top view of one embodiment of a lead frame in accordance with the present invention.

### DETAILED DESCRIPTION OF THE PREFERRED EMBODIMENTS

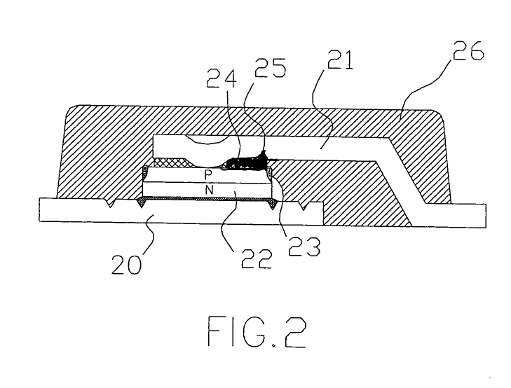

FIG. 2 illustrates a surface mount semiconductor device, such as a rectifier, manufactured according to an embodiment of the present invention. The semiconductor device comprises a bottom lead frame (20); a die (22) attached on the bottom lead frame (20); a top finger or clip (21) having a groove (25), such as a U or V-groove, attached on the die (22) by a conductive material (24), such as solder; and a molding compound (26) for molding the semiconductor device. The groove (25) is provided at a bottom side of the top finger (21) and is adjacent to the contact position between the top finger (21) and the die (22) so as to prevent the solder (24) from overflowing onto a chip passivation ring (23), thereby reducing the stress on the die (22) and increasing the reliability.

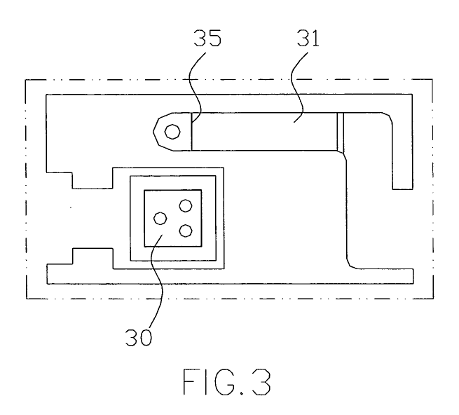

FIG. 3 illustrates one embodiment of a lead frame of the present invention implemented in a folded frame type approach. The lead frame can be used in the semiconductor device as shown in FIG. 2. The lead frame comprises a finger portion (31), such as a top finger or clip, having a groove (35), such as a U or V-groove shown in FIG. 2; and a die-attached portion (30) for attaching a die thereon. The groove (35) is provided at the bottom side of the finger portion (31) and adjacent to the contact position between the finger portion (31) and the die so as to prevent a solder from overflowing onto a chip passivation ring, reduce the stress on the die and increase the reliability.

Although the present invention and its advantage have been described in detail, it should be understood that various changes, substitutions and alternations can be made herein without departing from the spirit and scope of the invention as defined by the appended claims.

1. A semiconductor device, comprising
a bottom lead frame;
a die attached on the bottom lead frame;
a top finger attached to said die, wherein said top finger has a groove, wherein the groove is provided at a bottom surface of said top finger and adjacent to a contact position between said top finger and said die and the groove, and wherein the groove in said top finger contains conductive material that flowed into the groove upon attaching said top finger to said die; and
a molding compound for molding the semiconductor device.

2. The semiconductor device of claim 1, wherein said top finger is attached to said die with a conductive material.

3. The semiconductor device of claim 2, wherein said conductive material is solder.

4. (canceled)

5. (canceled)

6. The semiconductor material of claim 1, wherein the groove is a V-groove.

7. The semiconductor device of claim 1, wherein the semiconductor device is a rectifier.

8. The semiconductor device of claim 1, wherein the groove is located closer to a point of contact between said top finger and the die than a passivation ring of the die.

9. A lead frame for a semiconductor device, the lead frame comprising:
a finger portion having a top surface and a bottom surface, wherein the bottom surface includes a groove cut therein; and
a die-attached portion for attaching a die thereon,
wherein the groove provided in a bottom surface of said finger portion is adjacent to a contact position between said finger portion and the die, and wherein the groove in said top finger contains conductive material that flowed into the groove upon attaching said top finger to said die.

10. The lead frame of claim 9, wherein the groove is a U-groove.

11. The lead frame of claim 9, wherein the groove is a V-groove.

12. The lead frame of claim 9, wherein said finger portion is attached to said die with a conductive material.

13. The lead frame device of claim 12, wherein said conductive material is solder.

14. (canceled)

15. The lead frame of claim 9, wherein the semiconductor device is a rectifier.
